(19) United States
(12) Patent Application Publication
(10) Pub. No.: US 2017/0133996 A1
(43) Pub. Date: May 11, 2017

(54) METAL-INSULATOR-METAL (MIM) ARRAY FOR INTEGRATED RADIO FREQUENCY (RF) FILTER

(71) Applicant: QUALCOMM Incorporated, San Diego, CA (US)

(72) Inventors: Daeik Daniel Kim, Del Mar, CA (US); Chengjie Zuo, Santee, CA (US); David Francis Berdy, San Diego, CA (US); Changhan Hobie Yun, San Diego, CA (US); Mario Francisco Velez, San Diego, CA (US); Jonghae Kim, San Diego, CA (US)

(21) Appl. No.: 14/936,998

(22) Filed: Nov. 10, 2015

(51) Int. Cl. H03H 7/01; H03H 3/00; H01L 23/66; H01L 49/02; H01L 25/18

(52) U.S. Cl. CPC H03H 7/0115; H01L 28/10; H01L 28/40; H01L 25/18; H01L 23/66; H03H 3/00; H01L 2223/6672

(57) ABSTRACT

A circuit includes a localized metal-insulator-metal (MIM) capacitor array in a radio frequency (RF) front end circuit, which is integrated on a first die, and includes a localized common shared ground node within the localized MIM capacitor array, a plurality of inductors, and a plurality of RF filters. Each of the plurality of RF filters includes a plurality of passive resonant frequency circuits, and each of the plurality of passive resonant frequency circuits is implemented utilizing one or more MIM capacitors in the localized MIM capacitor array, and one or more of the plurality of inductors. The plurality of inductors may be arranged at a periphery of the localized MIM capacitor array on the first die or integrated on a second die, which is coupled to the first die. Each of the MIM capacitors in the localized MIM capacitor array has a different capacitance value.

### FIELD

The present disclosure pertains to a localized metal-insulator metal array for implementing passive resonant frequency circuits for radio frequency (RF) filters.

### BACKGROUND

Wireless communication networks are widely deployed to provide various communication services such as voice, video, packet data, messaging, broadcast, etc. These wireless networks may be multiple-access networks capable of supporting multiple users by sharing the available network resources. Examples of such multiple-access networks include Code Division Multiple Access (CDMA) networks, Time Division Multiple Access (TDMA) networks, Frequency Division Multiple Access (FDMA) networks, Orthogonal FDMA (OFDMA) networks, and Single-Carrier FDMA (SC-FDMA) networks.

A wireless communication network may include a number of access nodes (e.g. base stations, eNodeBs) that can support communication for a number of user equipment. A user equipment may communicate with an access node via the downlink and uplink. The downlink, which may also be referred to as a forward link, is the communication link from the access node to the user equipment, and the uplink, which may also be referred to a reverse link, refers to the communication link from the user equipment to the access node.

To improve the performance of wireless communications, it may be desirable to allow a user equipment to simultaneously communicate with one or more cells over multiple uplink grants from the cells, which can be referred to as carrier aggregation. The user equipment may thus utilize one or more carriers to communicate with each of the multiple cells. A primary cell can configure the user equipment to receive communications from the multiple cells over corresponding component carriers. Carrier aggregation may aggregate radio frequency carriers from a plurality of different frequency bands (e.g. cellular band 700 Mhz, and 1.9 GHz, wireless fidelity (Wi-Fi) band 2.4 GHz, and 5.8 GHz), in order to multiply the data rate.

Conventional metal-insulator-metal devices have capacitors that are randomly scattered and are typically subjected to large process variations, of the order of about 3% within the wafer and about 1.5% within the die. The scattering of the capacitors can result in variations in the responses of the inductors and capacitors tanks used to implement radio frequency (RF) filters, which translates to variations in the notch frequencies utilized to filter out undesired signals. The scattering of the capacitors results in longer signal routing distances to ground, which increases the parasitic inductance to ground. This makes the conventional metal-insulator-metal devices unsuitable for applications such as carrier aggregation, which requires high precision filtering of component carriers in disparate frequency bands. Furthermore, since these radio frequency filters are typically implemented utilizing passive networks comprising inductor capacitor tanks, the relatively large size of inductors results in a relatively large die size, which may present real estate challenges when installing on customer boards.

Therefore, a solution is needed that allows metal-insulator-metal devices suitable for applications such as carrier aggregation, which requires high precision filtering of component carriers in disparate frequency bands.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

According to an aspect, a circuit comprises a localized metal-insulator-metal capacitor array in a radio frequency front end circuit, which is integrated on a first die, and includes a localized common shared ground node within the localized metal-insulator-metal capacitor array, a plurality of inductors, and a plurality of radio frequency filters. Each of the plurality of radio frequency filters includes a plurality of passive resonant frequency circuits, and each of the plurality of passive resonant frequency circuits is implemented utilizing one or more metal-insulator-metal capacitors in the localized metal-insulator-metal capacitor array, and one or more of the plurality of inductors. In one aspect, the plurality of inductors may be arranged at a periphery of the localized metal-insulator-metal capacitor array on the first die. In another aspect, the plurality of inductors may be integrated on a second die, which is coupled to the first die. Each of the metal-insulator-metal capacitors in the localized metal-insulator-metal capacitor array may have a different capacitance value. The plurality of inductors are arranged on a first localized area of the first die, and the localized metal-insulator-metal capacitor array is arranged on a second localized area of the first die. In one aspect, the first die may include only passive circuits. The radio frequency front end circuit may be incorporated into at least one of a user equipment, a communications device, a mobile phone, a smartphone, a tablet computer, and/or a laptop computer.

According to an aspect, a method for manufacturing circuit comprises providing a localized metal-insulator-metal capacitor array in a radio frequency front end circuit, which is integrated on a first die, and includes a localized common shared ground node within the localized metal-insulator-metal capacitor array, providing a plurality of inductors, and providing a plurality of radio frequency filters in which each of the plurality of radio frequency filters includes a plurality of passive resonant frequency circuits, and each of the plurality of passive resonant frequency circuits is implemented utilizing one or more metal-insulator-metal capacitors in the localized metal-insulator-metal capacitor array, and one or more of the plurality of inductors.

The plurality of inductors may be arranged at a periphery of the localized metal-insulator-metal capacitor array on the first die. The plurality of inductors may be integrated on a second die, which is coupled to the first die, and the first die and the second die may include only passive circuits. Each of the metal-insulator-metal capacitors in the localized metal-insulator-metal capacitor array may have a different capacitance value. The plurality of inductors are arranged on a first localized area of the first die, and the localized metal-insulator-metal capacitor array is arranged on a second localized area of the first die.

According to another aspect, a circuit comprises a first integrated circuit die including a localized metal-insulator-metal capacitor array in a radio frequency front end circuit, and includes a localized common shared ground node within the localized metal-insulator-metal capacitor array, a plurality of inductors, means for coupling one or more metal-insulator-metal capacitors in the localized metal-insulator-metal capacitor array to one or more of the inductors to implement a plurality of passive resonant frequency circuits, and means for coupling the plurality of passive resonant frequency circuits to implement a plurality of radio frequency filters. The plurality of inductors may be arranged at a periphery of the localized metal-insulator-metal capacitor array on the first integrated circuit die. In another embodiment, the plurality of inductors may be integrated on a second integrated circuit die, which is coupled to the first integrated circuit die. Each of the metal-insulator-metal capacitors in the localized metal-insulator-metal capacitor array may have a different capacitance value. The plurality of inductors are arranged on a first localized area of the first die, and the localized metal-insulator-metal capacitor array is arranged on a second localized area of the first die. The first die may include only passive circuits.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### DRAWINGS

Various features, nature and advantages may become apparent from the detailed description set forth below when taken in conjunction with the drawings in which like reference characters identify correspondingly throughout.

FIG. 1 illustrates an exemplary wireless communications system in which user equipment utilize radio frequency filters implemented utilizing metal-insulator-metal capacitors having a single localized common shared ground node to handle carrier aggregation.

FIG. 2 is a block diagram conceptually illustrating examples of a transmitter/receiver chain for an access point device and a user equipment configured for handling carrier aggregation.

FIG. 3 is a block diagram conceptually illustrating an aggregation of component carriers for radio access technologies at a user equipment.

FIG. 4 is a high-level block diagram of a user equipment comprising a radio frequency front end circuit that utilizes a metal-insulator-metal capacitor array for implementing radio frequency filters for a multiplexer.

FIG. 5A is a block diagram illustrating a radio frequency filter comprising a plurality of passive resonant frequency circuits that are implemented utilizing a localized metal-insulator-metal capacitor array having a single localized common shared ground and a plurality of inductors that are on the same die.

FIG. 5B is a block diagram illustrating the radio frequency filter of FIG. 5A in which the plurality of inductors are arranged on a first localized area of the die, and the localized metal-insulator-metal capacitor array is arranged on a second localized area of the same die.

FIG. 6 is a graph illustrating frequency response for a low pass filter and a high pass filter for the radio frequency filter of FIG. 5A, which is a diplexer.

FIG. 7 is a diagram illustrating an implementation of radio frequency filters for a multiplexer utilizing a localized metal-insulator-metal capacitor array having a single localized common shared ground node on a first die, and inductors on a second die that is electrically coupled to the first die.

FIG. 8 is a flow chart illustrating configuration and operation of radio frequency filters in a radio frequency front end utilizing passive resonant frequency circuits.

FIG. 9 is a flow chart illustrating manufacturing of radio frequency filters in a radio frequency front end utilizing passive resonant frequency circuits.

### DETAILED DESCRIPTION

In the following description, specific details are given to provide a thorough understanding of the embodiments. However, it will be understood by one of ordinary skill in the art that the embodiments may be practiced without these specific detail. For example, circuits may be shown in block diagrams in order not to obscure the embodiments in unnecessary detail. In other instances, well-known circuits, structures and techniques may not be shown in detail in order not to obscure the embodiments.

### Overview

The present disclosure refers to apparatus and method of manufacture thereof for a circuit including a localized metal-insulator-metal capacitor array in a radio frequency front end circuit, a plurality of inductors, and a plurality of radio frequency filters. Each of the plurality of radio frequency filters includes a plurality of passive resonant frequency circuits, and each of the plurality of passive resonant frequency circuits is implemented utilizing one or more metal-insulator-metal capacitors in the localized metal-insulator-metal capacitor array, and one or more of the plurality of inductors. Each of the plurality of radio frequency filters may be utilized for carrier aggregation in which different carriers from a plurality of frequency bands are aggregated and each of the plurality of radio frequency filters provides accurate and sharp notch frequencies for filtering out undesired signals during the carrier aggregation. The localized metal-insulator-metal capacitor array is integrated on a first die, and comprises a single localized common shared ground node within the localized metal-insulator-metal capacitor array. The plurality of inductors may be integrated on the first die, or may be integrated on a second die, which is coupled to the first die. The plurality of inductors may be arranged on a first localized area of the first die, and the localized metal-insulator-metal capacitor array may be arranged on a second localized area of the first die. The first localized area of the first die is different from the second localized area of the first die. The localization or consolidation of the metal-insulator-metal capacitors in the localized metal-insulator-metal capacitor array minimizes global and local variation or mismatch to achieve high performance radio frequency filters to deliver high yield. The localization or consolidation of the metal-insulator-metal capacitor array may include consolidating or placing the metal-insulator-metal capacitors within the metal-insulator-metal capacitor array within close proximity of each other, so that the metal-insulator-metal capacitors are next to each other or side-by-side.

The techniques described herein may be used for various wireless communication networks such as CDMA, TDMA, FDMA, OFDMA, SC-FDMA and other networks. The terms “network” and “system” are often used interchangeably. A CDMA network may implement a radio technology such as Universal Terrestrial Radio Access (UTRA), cdma2000, etc. UTRA includes Wideband CDMA (WCDMA) and other variants of CDMA. cdma2000 covers IS-2000, IS-95 and IS-856 standards. A TDMA network may implement a radio technology such as Global System for Mobile Communications (GSM). An OFDMA network may implement a radio technology such as Evolved UTRA (E-UTRA), Ultra Mobile Broadband (UMB), Institute of Electrical and Electronics Engineers (IEEE) 802.11 (Wi-Fi), IEEE 802.16 (WiMAX), IEEE 802.20, Flash-OFDMA, etc. UTRA and E-UTRA are part of Universal Mobile Telecommunications System (UMTS). 3GPP LTE and LTE-Advanced (LTE-A) are new releases of UMTS that use E-UTRA. UTRA, E-UTRA, UMTS, Long Term Evolution (LTE), LTE-A and Global System for Mobile Communications (GSM) are described in documents from an organization named “3rd Generation Partnership Project” (3GPP). cdma2000 and UMB are described in documents from an organization named “3rd Generation Partnership Project 2” (3GPP2). The techniques described herein may be used for the wireless networks and radio technologies mentioned above as well as other wireless networks and radio technologies. For clarity, certain aspects of the techniques are described below for LTE, and LTE terminology is used in much of the description below.

Exemplary User Equipment with Radio Frequency Filters that Support Carrier Aggregation

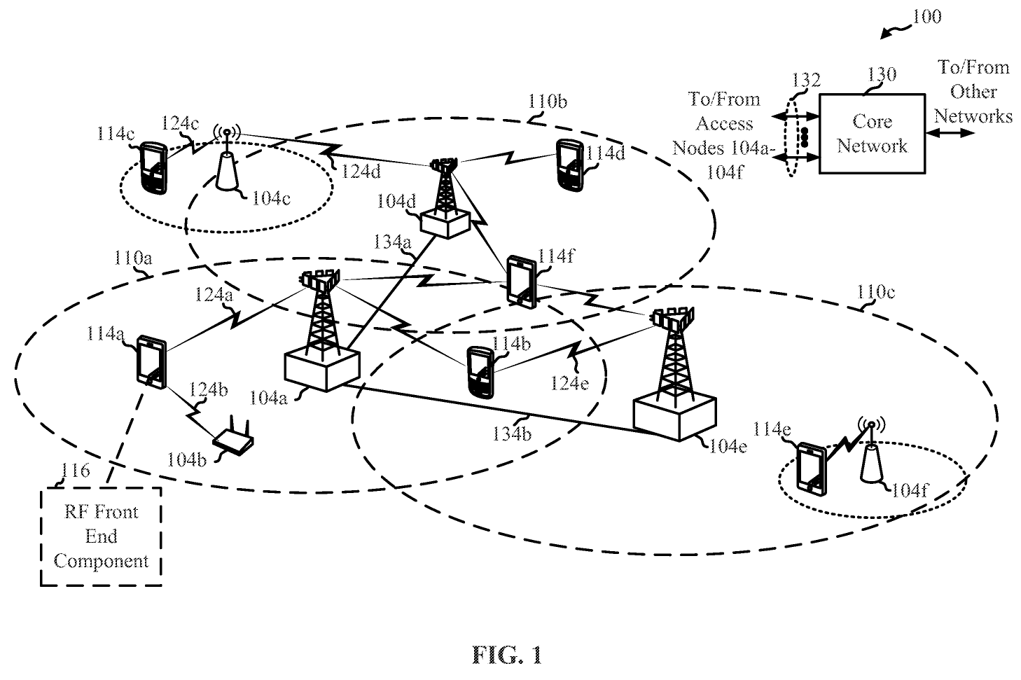

FIG. 1 illustrates an exemplary wireless communications system in which user equipment utilize radio frequency filters implemented utilizing metal-insulator-metal capacitors having a single localized common shared ground node to handle carrier aggregation. This example illustrates a wireless communications system 100. The wireless communications system 100 includes a plurality of access nodes (or cells) 104a, 104b, 104c, 104d, 104e, 104f, a plurality of user equipment 114a, 114b, 114c, 114d, 114e, 114f, and a core network 130. The access nodes (or cells) 104a, 104b, 104c, 104d, 104e, 104f may be collectively referenced as access nodes (or cells) 104. The plurality of user equipment 114a, 114b, 14c, 114d, 114e, 114f may be collectively referenced as user equipment 114.

The user equipment (UE) 114 may be dispersed throughout the wireless communications system 100, and each of the user equipment 114 may be stationary or mobile. A user equipment 114 may also be referred to by those skilled in the art as a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology. A user equipment 114 may be a cellular phone, a personal digital assistant, a wireless modem, a wireless communication device, a handheld device, a tablet computer, a laptop computer, a cordless phone, a wireless local loop station, or the like. A user equipment 114 may be able to communicate with an access point device such as a macro access node (e.g. macro base station), pico access node (e.g. pico base station), femto access node (e.g. femto base station), relays, access points, and the like.

The access nodes 104 may communicate with the user equipment 114 under the control of an access node controller (e.g. base station controller (not shown)), which may be part of the core network 130 or the access nodes 104 in various embodiments, in one or more cells provided by the access nodes 104. The access nodes 104 may communicate control information and/or user data with the core network 130 through first backhaul links 132. In embodiments, the access nodes 104 may communicate, either directly or indirectly, with each other over second backhaul links 134a, 134b, which may be wired or wireless communication links. The second backhaul links 134a, 134b may be collectively referenced as second backhaul links 134. The wireless communications system 100 may support operation on multiple carriers (waveform signals of different frequencies). Multi-carrier transmitters can transmit modulated signals simultaneously on the multiple carriers. For example, each of the communication links 124a, 124b, 124c, 124d, 124e may be a multi-carrier signal modulated according to the various radio technologies described above. The communication links 124a, 124b, 124c, 124d, 124e may be collectively referenced as communication links 124. Each modulated signal may be sent on a different carrier and may carry control information (e.g., reference signals, control channels, etc.), overhead information, data, etc. The wireless communications system 100 may also support operation on multiple flows at the same time. In some aspects, the multiple flows may correspond to multiple wireless wide area networks or cellular flows. In other aspects, the multiple flows may correspond to a combination of wireless wide area networks wireless wide area networks or cellular flows and wireless local area networks (WLAN) or wireless fidelity (Wi-Fi) flows.

The access nodes 104 may wirelessly communicate with the user equipment 114 via one or more base station antennas. Each of the access nodes 104 sites may provide communication coverage for a respective geographic coverage area 110. In some embodiments, the access nodes 104 may be referred to as a base transceiver station, a radio base station, an access point, a radio transceiver, a basic service set (BSS), an extended service set (ESS), a NodeB, eNodeB, Home NodeB, a Home eNodeB, or some other suitable terminology. The geographic coverage area 110 for each of the access nodes 104 may be divided into sectors making up only a portion of the coverage area (not shown). The wireless communications system 100 may include access nodes 104 of different types (e.g., macro, micro, femto, and/or pico access nodes). There may be overlapping coverage areas for different technologies.

In implementations, the wireless communications system 100 is an LTE/LTE-A network communication system. In LTE/LTE-A network communication systems, the terms evolved Node B (eNodeB) may be generally used to describe the access nodes 104. The wireless communications system 100 may be a Heterogeneous LTE/LTE-A network in which different types of access points, which may be referred to as NodeBs, provide coverage for various geographical regions. For example, each of the access nodes 104 may provide communication coverage for a macro cell, a pico cell, a femto cell, and/or other types of cell. A macro cell generally covers a relatively large geographic area (e.g., several kilometers in radius) and may allow unrestricted access by user equipment 114 with service subscriptions with the network provider. A pico cell would generally cover a relatively smaller geographic area (e.g., buildings) and may allow unrestricted access by user equipment 114 with service subscriptions with the network provider. A femto cell would also generally cover a relatively small geographic area (e.g., a home) and, in addition to unrestricted access, may also provide restricted access by user equipment 114 having an association with the femto cell (e.g., user equipment 114 in a closed subscriber group (CSG), user equipment 114 for users in the home, and the like). An access node 104 for a macro cell may be referred to as a macro access node (e.g. macro eNodeB). An access node 104 for a pico cell may be referred to as a pico access node (e.g. pico eNodeB). An access node 104 for a femto cell may be referred to as a femto access node or a home access node (e.g. home eNodeB). An access node 104 may support one or multiple (e.g., two, three, four, and the like) cells. The wireless communications system 100 may support use of LTE and wireless local area network (WLAN) or Wi-Fi by one or more of the user equipment 114.

The core network 130 may communicate with the access nodes 104 via first backhaul links 132 (e.g., SI interface, etc.). The access node 104 may also communicate with one another, e.g., directly or indirectly via second backhaul links 134 (e.g., X2 interface, etc.) and/or via the first backhaul links 132 (e.g., through core network 130). The wireless communications system 100 may support synchronous or asynchronous operation. For synchronous operation, the access nodes 104 may have similar frame timing, and transmissions from different access nodes 104 may be approximately aligned in time. For asynchronous operation, the access nodes 104 may have different frame timing, and transmissions from different access nodes 104 may not be aligned in time. The techniques described herein may be used for either synchronous or asynchronous operations.

The communication links 124 shown in the wireless communications system 100 may include uplink (UL) transmissions from one of the user equipment 114 to an access node 104, and/or downlink (DL) transmissions, from an access node 104 to one of the user equipment 114. The downlink transmissions may also be called forward link transmissions while the uplink transmissions may also be called reverse link transmissions.

In certain aspects of the wireless communications system 100, one or more of the user equipment 114 may be configured to support carrier aggregation (CA) with one or more cells, where each cell can be provided by one or more access nodes 104. The access nodes 104 that are used for carrier aggregation may be the same access nodes 104 (e.g., where the multiple cells correspond to the same access nodes 104), may be collocated, or may be connected through fast connections. In any case, coordinating the aggregation of component carriers for wireless communications between the user equipment 114 and the access node(s) 104 may be carried out more easily because information can be readily shared between the various cells being used to perform the carrier aggregation. In an example, the user equipment 114 can communicate with a primary cell (PCell) that provides a primary component carrier (PCC), and/or at least one secondary cell (SCell) that provides a secondary component carrier (SCC). In some configurations, the primary cell may provide one or more secondary component carrier in addition or alternatively to the secondary component carrier. In an example, the primary cell may control configuration of the primary component carrier and the secondary component carrier to the user equipment 114. When the access nodes 104 that are used for carrier aggregation are non-collocated (e.g., far apart or do not have a high-speed connection between them), then coordinating the aggregation of component carriers may involve additional aspects.

In an aspect, one or more of the user equipment 114 may comprise a radio frequency front end circuit that is configured to support carrier aggregation. For example, the user equipment 114a may comprise a radio frequency (RF) front end circuit 116 to handle carrier aggregation. The radio frequency front end circuit 116 comprise a localized metal-insulator-metal capacitor array, a plurality of inductors, and a plurality of radio frequency filters. Each of the plurality of radio frequency filters includes a plurality of passive resonant frequency circuits, and each of the plurality of passive resonant frequency circuits is implemented utilizing one or more metal-insulator-metal capacitors in the localized metal-insulator-metal capacitor array, and one or more of the plurality of inductors. The localized metal-insulator-metal capacitor array is integrated on a first die, and comprises a single localized common shared ground node within the localized metal-insulator-metal capacitor array. The localized metal-insulator-metal capacitor array with the single localized common shared ground node is utilized to implement high precision radio frequency filters such as diplexers, triplexers, and quadplexers, for use in application such as carrier aggregation. The high precision radio frequency filters that are implemented utilizing the localized metal-insulator-metal capacitor array with the single localized common shared ground node, which have minimal variations in notch frequencies to allow more precise selection of signals in a desired frequency band, and rejection of undesired signals in other frequency bands. In other words, the notch frequency for the inductor/capacitor (LC) tank circuit utilized by these radio frequency filters has to be really sharp/deep and accurate to more precisely discriminate amongst the harmonic signals in the various frequency bands being aggregated. A frequency of an inductor/capacitor tank circuit is generally tuned to generate a notch at the location of an undesired harmonic signal in order the filter out the undesired harmonic.

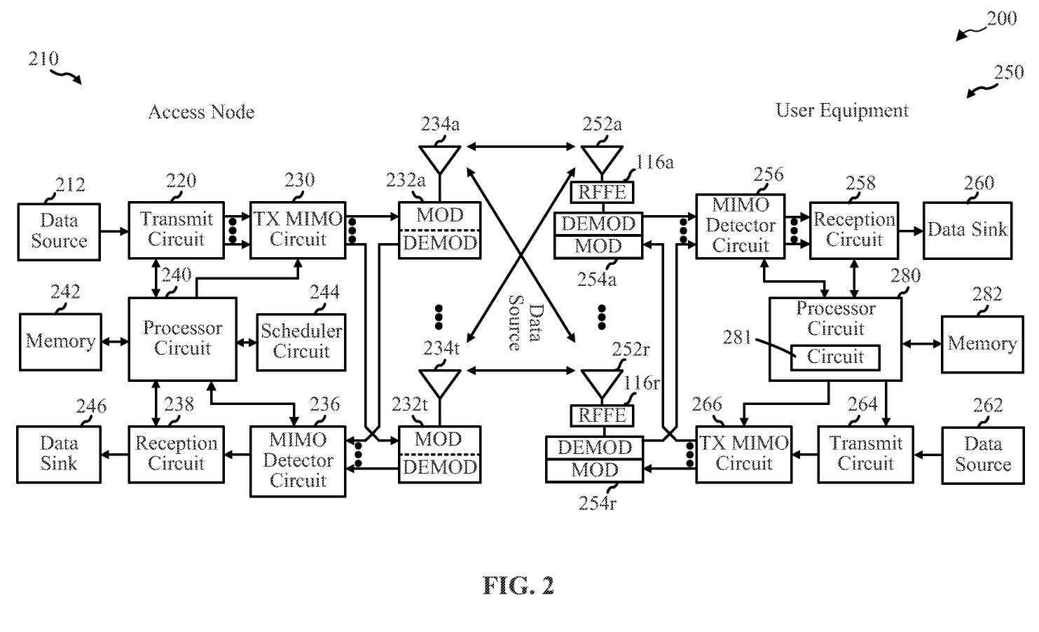

FIG. 2 is a block diagram conceptually illustrating examples of a transmitter/receiver chain for an access point device and a user equipment configured for handling carrier aggregation. For example, an access node 210 and the user equipment 250 of a system 200, as shown in FIG. 2, may be one of the access nodes 104 and one of the user equipment 114 in FIG. 1, respectively. In some aspects, the access node 210 may support carrier aggregation and/or multiple connectivity. The user equipment 250 may receive configuration information from the access node 210 via the primary cell. The access node 210 may be equipped with antennas 234a-234t, and the user equipment 250 may be equipped with antennas 252a-252r. The antennas 234a-234t may be collectively referenced as antennas 234. The antennas 252a-252r may be collectively referenced as antennas 252.

At the access node 210, an access node transmit circuit 220 may receive data from an access node data source 212 and control information from an access node processing circuit 240. The control information may be carried on the physical broadcast channel (PBCH), physical control format indicator channel (PCFICH), physical hybrid automatic repeat/request (HARQ) indicator channel (PHICH), physical downlink control channel (PDCCH), etc. The data may be carried on the physical downlink shared channel (PDSCH), etc. The access node transmit circuit 220 may process (e.g., encode and symbol map) the data and control information to obtain data symbols and control symbols, respectively. The access node transmit circuit 220 may also generate reference symbols, e.g., for the primary synchronization signal (PSS), secondary synchronization signal (SSS), and cell-specific reference signal (RS). An access node transmit (TX) multiple-input multiple-output (MIMO) circuit 230 may perform spatial processing (e.g., precoding) on the data symbols, the control symbols, and/or the reference symbols, if applicable, and may provide output symbol streams to the access node modulators/demodulators (MODs/DEMODs) 232a-232t. The access node modulators/demodulators 232a-232t may be collectively referenced as modulators/demodulators 232. Each of the access node modulators/demodulators 232, which may also be referred to as access node modulators/demodulators circuits 232, may process a respective output symbol stream (e.g., for orthogonal frequency division multiplexing, etc.) to obtain an output sample stream. Each of the access node modulators/demodulators 232 may further process (e.g., convert to analog, amplify, filter, and upconvert) the output sample stream to obtain a downlink signal. Downlink signals from the modulators/demodulators 232a-232t may be transmitted via the antennas 234a-234t, respectively.

At the user equipment 250, the user equipment antennas 252a-252r may receive the downlink signals from the access node 210 and may provide received signals to the user equipment modulators/demodulators (MODs/DEMODs) 254a-254r, respectively. The user equipment modulators/demodulators 254a-254r may be collectively referenced as modulators/demodulators 254. Each of the user equipment modulators/demodulators 254, which may be referred to as modulators/demodulators circuits, 254 may condition (e.g., filter, amplify, downconvert, and digitize) a respective received signal to obtain input samples. Each of the user equipment modulators/demodulators 254a-254r may be coupled to a corresponding one of the radio frequency front end (RFFE) circuit 116a-116r, respectively. The radio frequency front end circuit 116a-116r may be collectively referenced as radio frequency front end circuits 116. For example, the user equipment modulator/demodulator 254a may be coupled to the radio frequency front end circuit 116a to handle carrier aggregation. Each of the radio frequency front end circuits 116 comprise a localized metal-insulator-metal capacitor array, a plurality of inductors, and a plurality of radio frequency filters. Each of the plurality of radio frequency filters includes a plurality of passive resonant frequency circuits, and each of the plurality of passive resonant frequency circuits is implemented utilizing one or more metal-insulator-metal capacitors in the localized metal-insulator-metal capacitor array, and one or more of the plurality of inductors. The localized metal-insulator-metal capacitor array is integrated on a first die, and comprises a single localized common shared ground node within the localized metal-insulator-metal capacitor array. The localized metal-insulator-metal capacitor array with the single localized common shared ground node is utilized to implement radio frequency filters such as diplexers, triplexers, and quadplexers, for use in application that require high precision radio frequency filters such as carrier aggregation.

Each of the user equipment modulator/demodulator 254 may further process the input samples (e.g., for orthogonal frequency division multiplexing, etc.) to obtain received symbols. A user equipment MIMO detector circuit 256 may obtain received symbols from all the user equipment modulators/demodulators 254a-254r, and perform MIMO detection on the received symbols if applicable, and provide detected symbols. A user equipment reception circuit 258 may process (e.g., demodulate, deinterleave, and decode) the detected symbols, provide decoded data for the user equipment 250 to a user equipment data sink 260, and provide decoded control information to a user equipment processing circuit 280.

On the uplink, at the user equipment 250, a user equipment transmit circuit 264 may receive and process data (e.g., for the PUSCH) from a user equipment data source 262 and control information (e.g., for the PUCCH) from the user equipment processing circuit 280. The user equipment transmit circuit 264 may also generate reference symbols for a reference signal. The symbols from the user equipment transmit circuit 264 may be precoded by a user equipment TX MIMO circuit 266 if applicable, further processed by the user equipment modulator/demodulators 254a-254r (e.g., for SC-FDM, etc.), and transmitted to the access node 210. At the access node 210, the uplink signals from the user equipment 250 may be received by the access node antennas 234, processed by the access node modulators/demodulators 232, detected by the access node MIMO detector circuit 236 if applicable, and further processed by an access node reception circuit 238 to obtain decoded data and control information sent by the user equipment 250. The access node reception circuit 238 may provide the decoded data to an access node data sink 246 and the decoded control information to the access node processing circuit 240.

The access node processing circuit 240 and the user equipment processing circuit 280 may direct the operation at the access node 210 and the user equipment 250, respectively. In some aspects, at least a portion of the execution of these functional blocks and/or processes may be performed by a circuit 281 in the user equipment processing circuit 280. The access node memory 242 and the user equipment memory 282 may store data and program codes for the access node 210 and the user equipment 250, respectively. For example, the user equipment memory 282 may store configuration information for carrier aggregation and/or multiple connectivity provided by the access node 210 and/or another access node. A scheduler circuit 244 may be used to schedule user equipment 250 for data transmission on the downlink and/or uplink.

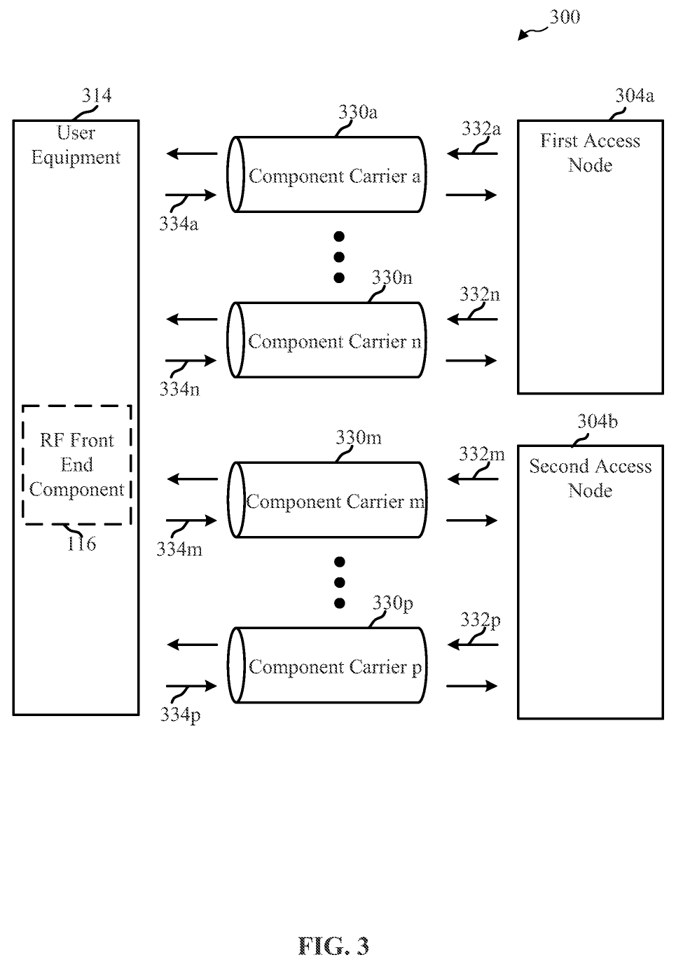

FIG. 3 is a block diagram conceptually illustrating an aggregation of component carriers for radio access technologies at a user equipment. The aggregation may occur in a system 300 including a multi-mode user equipment 314, which can communicate with a first access node 304a (e.g., eNodeB, base station, etc.) using one or more component carriers (CC) a through n (CCa-CCn), and/or with a second access node 304b using one or more component carriers m through p (CCm-CCp). For example, the first access node 304a and/or the second access node B 304b may include an AP, femto cell, pico cell, etc.

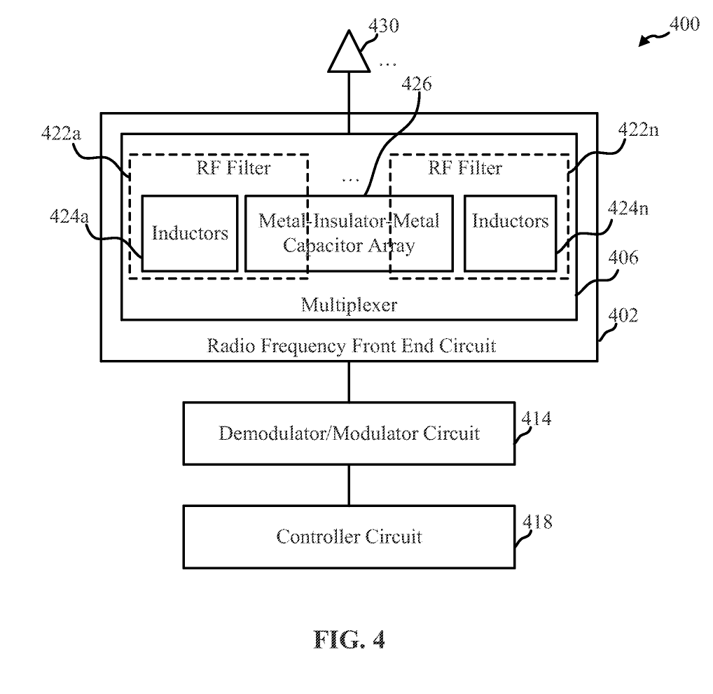

The user equipment 314 may be a multi-mode user equipment in this example that supports more than one radio access technology (RAT). For example, the user equipment 314 may support at least a Wireless Wide Area Network (WWAN) radio access technology (e.g., LTE) and/or a WLAN radio access technology (e.g., Wi-Fi). A multi-mode user equipment may also support carrier aggregation and/or multiple connectivity carrier aggregation using one or more RATs, as described herein. The user equipment 314 may be an example of one of the user equipment illustrated in FIG. 1, FIG. 2, and FIG. 4. The first access node 304a and/or the second access node 304b may be an example of one of the access nodes 104 of FIG. 1, and FIG. 2. While only one user equipment 314, one first access node 304a, and one second access node 304b are illustrated in FIG. 3, it will be appreciated that the system 300 can include any number of the user equipment 314, and the access nodes 304a and 304b. In one example, the user equipment 314 can communicate with the first access node 304a over one or more component carriers 330a to 330n (CCa-CCn), for example LTE component carriers, while communicating with another access node such as the second access node 304b over another one or more component carriers 330m to 330p (CCm-CCp), for example, LTE component carriers.

The first access node 304a can transmit information to the user equipment 314 over forward (downlink) channels 332a through 332n (332a-332n) on component carriers 330a through 330n (CCa-CCn). In addition, the user equipment 314 can transmit information to the first access node 304a over reverse (uplink) channels 334a through 334n (334a-334n) on component carriers 330a through 330n (CCa-CCn). Similarly, the second access node 304b may transmit information to the user equipment 314 over forward (downlink) channels 332m through 332p on component carriers 330m through 330p (CCm-CCp). In addition, the user equipment 314 may transmit information to the second access node 304b over reverse (uplink) channels 334m through 334p (334m-334p) on component carriers 330m through 330p (CCm-CCp).

In describing the various entities of FIG. 3, as well as other figures associated with some of the disclosed embodiments, for the purposes of explanation, the nomenclature associated with a 3GPP LTE or LTE-A wireless network is used. However, it is to be appreciated that the system 300 can operate in other networks such as, but not limited to, an OFDMA wireless network, a CDMA network, a 3GPP2 CDMA2000 network and the like.

### Exemplary Radio Frequency Front End in a User Equipment

FIG. 4 is a high-level block diagram of a user equipment 400 comprising a radio frequency front end circuit that utilizes a metal-insulator-metal capacitor array 426 for implementing radio frequency filters for a multiplexer 406. The metal-insulator-metal capacitor array 426 may also be referred to as a consolidated or localized metal-insulator-metal capacitor array 426. The localization or consolidation of the metal-insulator-metal capacitor array 426 may include consolidating or placing the metal-insulator-metal capacitors within the metal-insulator-metal capacitor array 426 within close proximity of each other, so that the metal-insulator-metal capacitors are next to each other or side-by-side. The radio frequency front end circuit 402 comprises a multiplexer 406 coupled to one or more antennas, which are collectively referenced as 430. The radio frequency front end circuit 402 is coupled to the demodulator/modulator circuit 414, and the demodulator/modulator circuit 414 is coupled to a controller circuit 418. The user equipment 400 may be an example of one of the user equipment of FIG. 1, FIG. 2, and FIG. 3. The radio frequency front end circuit 402 may be an example of the radio frequency front end (RFFE) 116a-116r of FIG. 2. The demodulator/modulator circuit 414 may be an example of the user equipment modulators/demodulators (MODs/DEMODs) circuits 254a-254r of FIG. 2. The controller circuit 418 may be an example of the user equipment processing circuit 280.

The controller circuit 418 may comprise a baseband processor or other hardware processor or circuit such as a digital signal processor that is operable to process demodulated signals and signals to be modulated.

The multiplexer 406 comprises a plurality of inductors 424a-424n and a localized metal-insulator-metal capacitor array 426. The localized metal-insulator-metal capacitor array 426 comprises a plurality of metal-insulator-metal capacitors. One or more of the plurality of inductors 424a-424n and one or more of the metal-insulator-metal capacitors in the localized metal-insulator-metal capacitor array 426 are utilized to implement one or more of the radio frequency filters 422a-422n for the multiplexer 406. The multiplexer 406 may be, for example, a diplexer circuit or diplexer, a triplexer circuit or triplexer, a quadplexer circuit or quadplexer, or the like. In one embodiment, the localized metal-insulator-metal capacitor array 426, and the plurality of inductors 424a-424n may be integrated on a first die. In another embodiment, the localized metal-insulator-metal capacitor array 426 may be arranged or located at a first localized area, location or region on the first die, and the plurality of inductors 424a-424n may be arranged or located at a second localized area, location or region on the first die. The first localized area, location or region on the first die is different from the second localized area, location or region on the first die. In another embodiment, the localized metal-insulator-metal capacitor array 426 may be integrated in a first die, and the plurality of inductors 424a-424n and may be integrated on a second die. The multiplexer 406 may be utilized for carrier aggregation.

### Exemplary Implementation of Radio Frequency Filters Utilizing a Metal-Insulator-Metal Capacitor Array Having a Single Localized Common Shared Ground Node

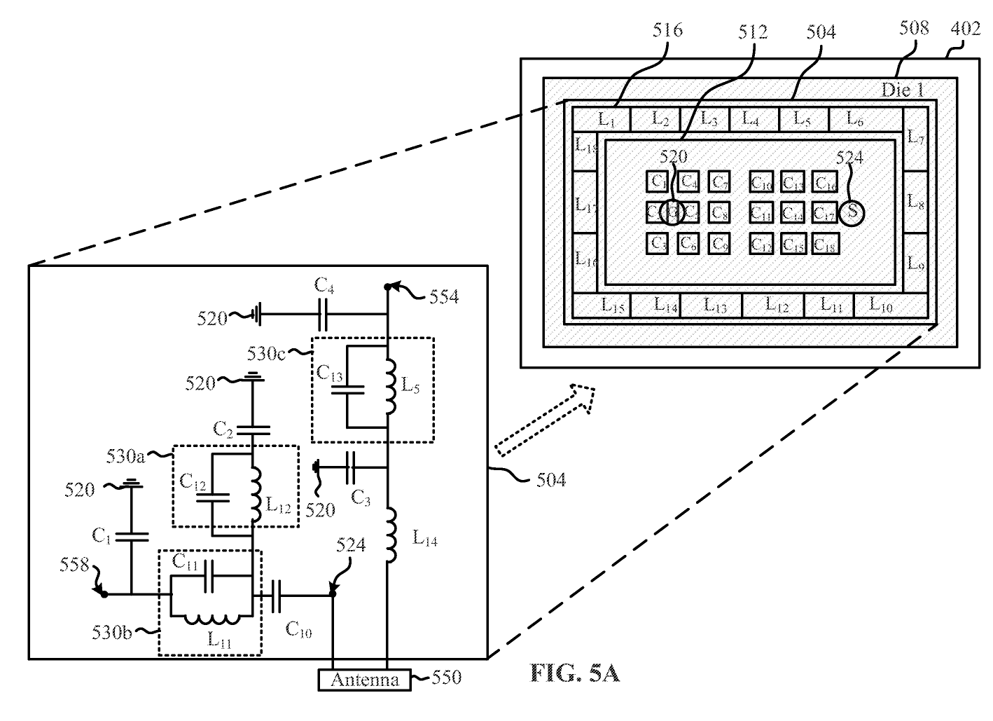

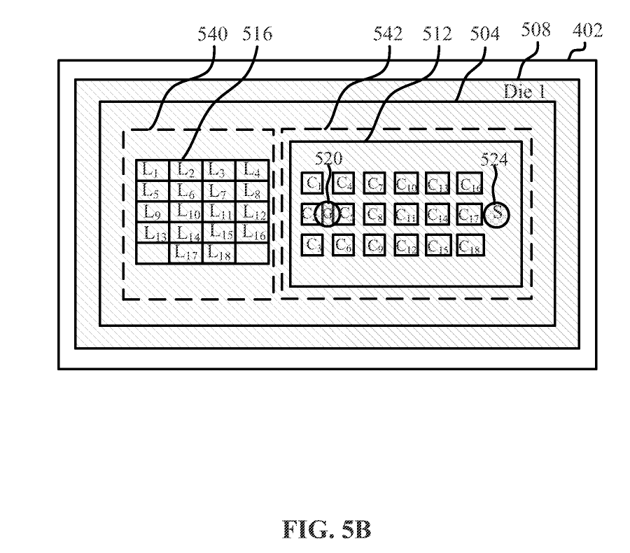

FIG. 5A is a block diagram illustrating a radio frequency filter 504 comprising a plurality of passive resonant frequency circuits that are implemented utilizing a localized metal-insulator-metal capacitor array having a single localized common shared ground and a plurality of inductors that are on the same die. The radio frequency filter 504 may be implemented utilizing passive components, which includes a plurality of inductors L₁-L₁₈, and a localized metal-insulator-metal capacitor array 512, which comprises a plurality of metal-insulator-metal capacitors C₁-C₁₈. The radio frequency filter 504 is configured to implement a diplexer. The radio frequency front end circuit 402 comprises the radio frequency filter 504.

The localized metal-insulator-metal capacitor array 512, which comprises the plurality of metal-insulator-metal capacitors C₁-C₁₈, is integrated on a single die 508. The localized metal-insulator-metal capacitor array 512 comprises a single localized common shared ground (G) node 520, which is located on the die 508. As illustrated in FIG. 5A, the metal-insulator-metal capacitors C₁-C₉ in the localized metal-insulator-metal capacitor array 512 are electrically coupled to the single localized common shared ground (G) node 520, which is located on the die 508, and the metal-insulator-metal capacitors C₁₀-C₁₈ in the localized metal-insulator-metal capacitor array 520 are electrically coupled to the signal (S) node 524. Each of the metal-insulator-metal capacitors C₁-C₁₈ may have a different capacitance value, and may be fabricated with thin copper and high K dielectric.

The radio frequency filter 504 may comprise a plurality of passive resonant radio frequency circuits 530a, 530b, and 530c. The passive resonant radio frequency circuits 530a, 530b, and 530c may also be referred to as inductor-capacitor (LC) tanks. Each of the passive resonant radio frequency circuits 530a, 530b, and 530c is implemented utilizing one or more metal-insulator-metal capacitor array capacitors C₁-C₁₈ in the localized metal-insulator-metal capacitor array 520, and one or more of the plurality of inductors L₁-L₁₈. The passive resonant radio frequency circuit 530a may be implemented utilizing metal-insulator-metal capacitor array capacitor C₁₂ in the localized metal-insulator-metal capacitor array 512, and the inductor L₁₂. The passive resonant radio frequency circuit 530b may be implemented utilizing metal-insulator-metal capacitor array capacitor C₁₁ in the localized metal-insulator-metal capacitor array 512, and the inductor L₁₁. The passive resonant radio frequency circuit 530c may be implemented utilizing metal-insulator-metal capacitor array capacitor C₁₃ in the localized metal-insulator-metal capacitor array 512, and the inductor L₅. The radio frequency filter 504 may comprise metal-insulator-metal capacitors C₁, C₂, C₃, C₄, and C₁₀, and inductor L₁₄. The metal-insulator-metal capacitors C₁, C₂, C₃, C₄ are electrically coupled to the single localized common shared ground (G) node 520, which is located on the die 508. The metal-insulator-metal capacitor C₁₀, and the inductor L₁₄ are electrically coupled to the antenna 550. The metal-insulator-metal capacitor C₁₀ may be coupled to the signal (S) node 524.

The localized metal-insulator-metal capacitor array 512, which comprises the plurality of metal-insulator-metal capacitors C₁-C₁₈, is arranged so that each of the plurality of metal-insulator-metal capacitors C₁-C₁₈ are located away from the edges of the die 508 in order to mitigate the effects of corner ball failure. Corner ball failure refers to the phenomenon in which the solder balls at the corners of the die are generally the first to fail. The consolidation of the metal-insulator-metal capacitors C₁-C₁₈ in the metal-insulator-metal capacitor array 512 may also result in more spatial uniformity, better uniformity in the capacitance values, and more cost effective area utilization. The consolidation of the metal-insulator-metal capacitors C₁-C₁₈ provides a reduction in size of the radio frequency filter 504 from approximately 3 mm to 1.5 mm when compared with conventional radio frequency filters in which the capacitors are scattered. This reduction in size translates into an approximate 1.5% reduction within the wafer variation, and an approximate 1.0% reduction within the die variation.

The use of a single localized common shared ground (G) node 520, which is located on the die 508, achieves a better process control over convention front end-of-line (FEOL) metal-insulator-metal capacitors, and offers a stronger ground connection by sharing the ground node 520 within the die 508. The single localized common shared ground (G) node 520, which is located on the die 508, is also immune to corner ball failure, and less sensitive to solder ball height change. In general, the greater the signal routing, the greater the parasitic inductance to ground. Since the metal-insulator-metal capacitors C₁-C₉ in the localized metal-insulator-metal capacitor array 512 are electrically coupled to the single localized common shared ground (G) node 520, the signal routing is reduced, thereby resulting in significantly less parasitic inductance, when compared to metal-insulator-metal capacitors that are scattered on a die, and don't utilize a single localized common shared ground. The stronger ground connection provided by sharing the ground node 520 within the die 508 enables a strong die ground-to-printed-circuit-board connection.

The radio frequency 504, which is a diplexer, includes a low band (LB) port 554, and a high band (HB) port 558. The passive resonant radio frequency circuits 530a, and 530b determines the output frequency of signals from the high band port 558. In this regard, the values of the capacitor and inductor in each of the passive resonant radio frequency circuits 530a, and 530b controls the notch frequency of signals that are output from the high band port 558. The passive resonant radio frequency circuit 530c determines the output frequency of signals from the low band port 554. In this regard, the values of the capacitor and inductor in the passive resonant radio frequency circuits 530c controls the notch frequency of signals that are output from the low band port 554.

For carrier aggregation, the passive resonant radio frequency circuits 530a, 530b, and 530c are tuned or configured to generate notches that fall on a harmonic of a component carrier when aggregating the component carriers from different frequency bands. Since the harmonic of the component carriers will interfere with the component carriers that are being aggregated, the generated notches have to be very sharp and deep in order to precisely filter out the harmonic and facilitate accurate aggregation of the component carriers.

FIG. 5B is a block diagram illustrating the radio frequency filter of FIG. 5A in which the plurality of inductors are arranged on a first localized area of the die, and the localized metal-insulator-metal capacitor array is arranged on a second localized area of the same die. The radio frequency front end circuit 402 comprises the radio frequency filter 504. The radio frequency filter 504 may be implemented utilizing passive components, which includes the plurality of inductors L₁-L₁₈, 516, and the localized metal-insulator-metal capacitor array 512, which comprises a plurality of metal-insulator-metal capacitors C₁-C₁₈. The plurality of inductors 516, and the localized metal-insulator-metal capacitor array 512 are integrated on a single die 508. In an embodiment, the plurality of inductors 516 are arranged on a first localized area or region 540 of the die 508, and the localized metal-insulator-metal capacitor array 512 is arranged on a second localized area or region 542 of the die 508. The first localized area or region 540 of the die 508, and the second localized area or region 542 of the die 508 are different areas or regions of the die 508.

The localization of the metal-insulator-metal capacitor array 512 may include consolidating or placing the metal-insulator-metal capacitors C₁-C₁₈ within the metal-insulator-metal capacitor array 512 within close proximity of each other, so that the metal-insulator-metal capacitors C₁-C₁₈ are next to each other or side-by-side. The localization of the plurality of inductors may include consolidating or placing the plurality of inductors L₁-L₁₅ within close proximity of each other, so that the plurality of inductors L₁-L₁₈ are next to each other or side-by-side.

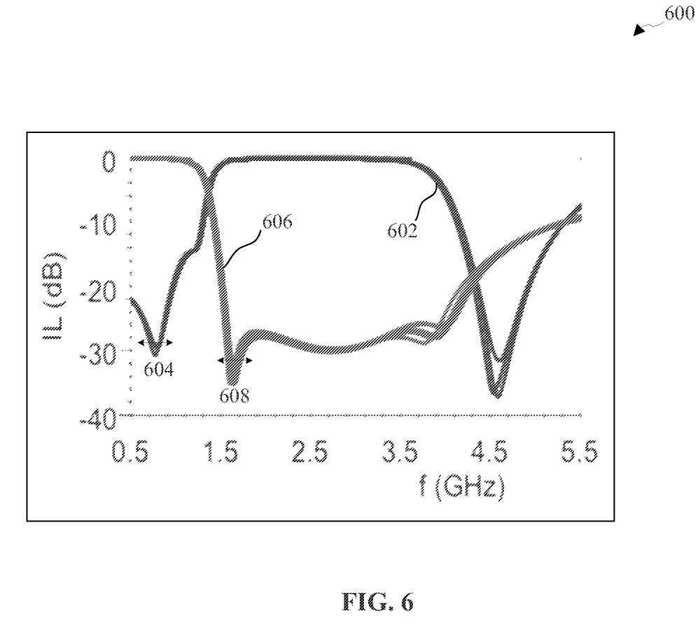

FIG. 6 is a graph 600 illustrating frequency response for a low pass filter and a high pass filter for the radio frequency filter 504 of FIG. 5A, which is a diplexer. The graph 600 shows illustrate the gain in decibels (dB) along the y-axis versus the frequency in gigahertz (GHz) along the x-axis. The notch 604 on the frequency response curve 602 is generated by the passive resonant radio frequency circuit 530c, at approximately 0.75 GHz, and correspond to an output of the low band port 554. The notch 608 on the frequency response curve 606 is generated by the passive resonant radio frequency circuits 530a, and 530b, at approximately 1.65 GHz, and correspond to an output of the high band port 558.

### Exemplary Implementation of Radio Frequency Filters Utilizing a First Die and a Second Die

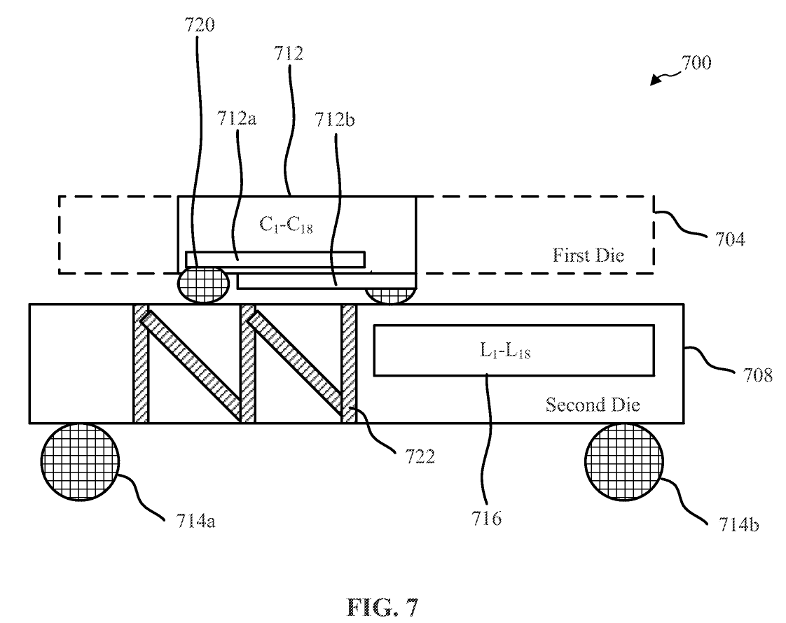

FIG. 7 is a diagram illustrating an assembly 700 of radio frequency filters for a multiplexer utilizing a localized metal-insulator-metal capacitor array having a single localized common shared ground node 710 on a first die 704, and inductors on a second die 708 that is electrically coupled to the first die. FIG. 7 illustrates a first die 704, that is electrically coupled to, and stacked on a second die 708. The assembly 700 may be electrically coupled to, for example, a printed circuit board (PCB) such as a customer board, via the solder ball 714a, and 714b.

The first die 704 may comprise a localized metal-insulator-metal capacitor array 712, which comprises a single localized common shared ground node 720 that may be located on the first die 704. The localized metal-insulator-metal capacitor array 712 may be substantially similar to the localized metal-insulator-metal capacitor array 512 that is illustrated in FIG. 5A, and may comprise the plurality of metal-insulator-metal capacitors C₁-C₁₈. A first plate 712a, and a second plate 712b of a single metal-insulator-metal capacitor within the localized metal-insulator-metal capacitor array 712 is illustrated. Although the localized metal-insulator-metal capacitor array 712, which includes a single localized common shared ground node 720, comprises a plurality of metal-insulator-metal capacitors as illustrated in FIG. 5A, only the first plate 712a and second plate 712b of a single metal-insulator-metal capacitor is shown in FIG. 7 for simplicity. The first die 704 may, for example, be flip chip bonded to the second die 708. Other methods may be utilized for electrically coupling the first die 704 to the second die 708. The first die 704 may be referred to as a capacitor substrate.

The second die 708 may comprise a plurality of inductors 716, and vias 722. The plurality of inductors 716 may be substantially similar to the plurality of inductors 516 that are illustrated in FIG. 5A, and may comprise the plurality of inductors L₁-L₁₈. The vias 722 may comprise, for example, through glass vias. The second die 708 may be referred to as an inductor substrate. In some embodiments, the second die 708 may be a package substrate. The solder ball 714a, and 714b may be coupled to the second die 708, and may enable coupling of the assembly 700 to, for example, a printed circuit board.

A radio frequency filter such as the radio frequency filter 504 illustrated in FIG. 5A, may be implemented utilizing one or more of the metal-insulator-metal capacitors C₁-C₁₈ in the localized metal-insulator-metal capacitor array 712, and one or more of the plurality of inductors L₁-L₁₈, 716. In this regard, the assembly 700 may be configured to implement a multiplexer such as a diplexer.

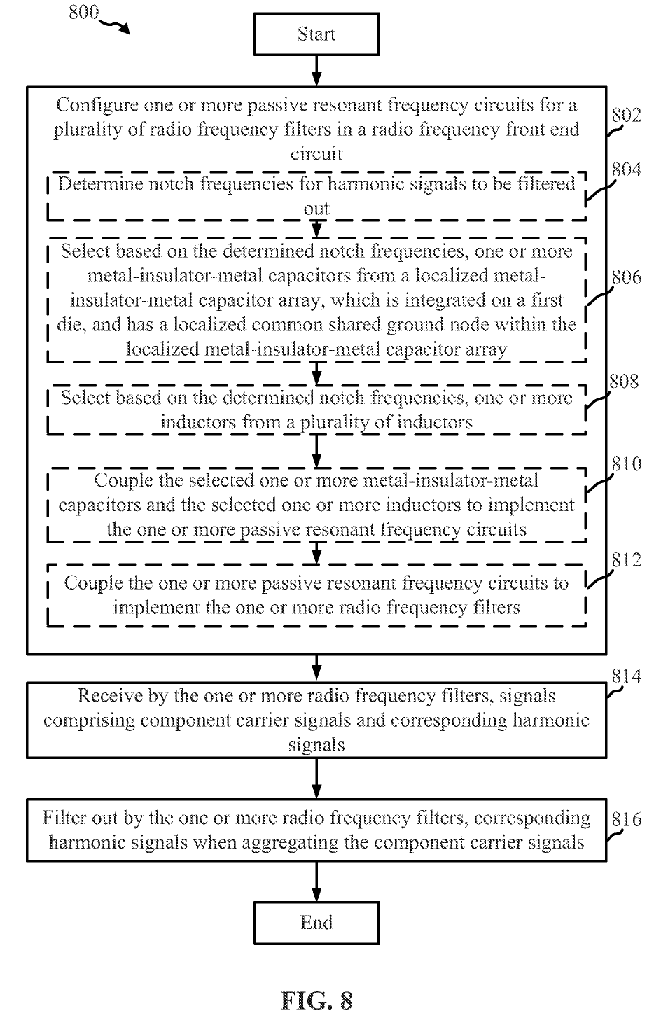

FIG. 8 is a flow chart illustrating configuration and operation of radio frequency filters in a radio frequency front end utilizing passive resonant frequency circuits. Configure one or more passive resonant frequency circuits 530a, 530b, 530c for a plurality of radio frequency filters 504 in a radio frequency front end circuit 402 at 802. Determine notch frequencies for harmonic signals to be filtered out at 804. Select based on the determined notch frequencies, one or more of the metal-insulator-metal capacitors C₁-C₁₈ from a localized metal-insulator-metal capacitor array 512, which is integrated on a first die 508, and has a localized common shared ground node 520 within the metal-insulator-metal capacitor array 512 at 806. Select based on the determined notch frequencies, one or more inductors from a plurality of inductors L₁-L₁₈ at 808. Couple the selected one or more metal-insulator-metal capacitors and the selected one or more inductors to implement the one or more passive resonant frequency circuits 530a, 530b, 530c at 810. Couple the one or more passive resonant frequency circuits 530a, 530b, 530c to implement the one or more radio frequency filters 504 at 812. Receive by the one or more radio frequency filters 504, signals comprising component carrier signals and corresponding harmonic signals at 814. Filter out by the one or more radio frequency filters 530a, 530b, 530c, corresponding harmonic signals when aggregating the component carrier signals at 816.

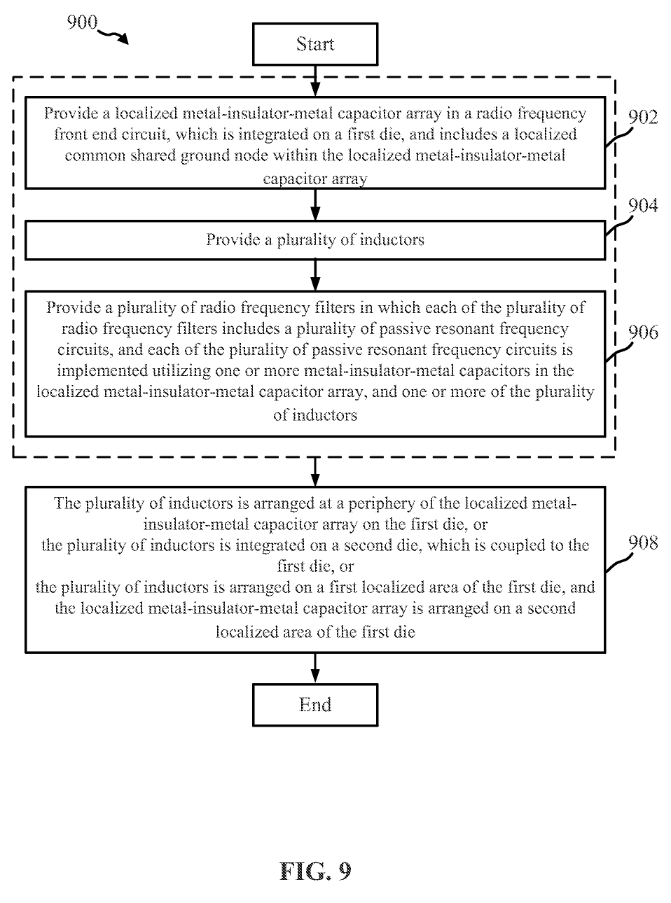

FIG. 9 is a flow chart illustrating manufacturing of radio frequency filters in a radio frequency front end utilizing passive resonant frequency circuits. Provide a localized metal-insulator-metal capacitor array in a radio frequency front end circuit, which is integrated on a first die, and includes a localized common shared ground node within the localized metal-insulator-metal capacitor array at 902. Provide a plurality of inductors at 904. Provide a plurality of radio frequency filters in which each of the plurality of radio frequency filters includes a plurality of passive resonant frequency circuits, and each of the plurality of passive resonant frequency circuits is implemented utilizing one or more metal-insulator-metal capacitors in the localized metal-insulator-metal capacitor array, and one or more of the plurality of inductors at 906. The plurality of inductors is arranged at a periphery of the localized metal-insulator-metal capacitor array on the first die, or the plurality of inductors is integrated on a second die, which is coupled to the first die, or the plurality of inductors is arranged on a first localized area of the first die, and the localized metal-insulator-metal capacitor array is arranged on a second localized area of the first die.

One or more of the components, steps, features and/or functions illustrated in the Figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the Figures may be configured to perform one or more of the methods, features, or steps described in the Figures. The novel algorithms described herein may also be efficiently implemented in software and/or embedded in hardware.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

Moreover, a storage medium may represent one or more devices for storing data, including read-only memory (ROM), random access memory (RAM), magnetic disk storage mediums, optical storage mediums, flash memory devices and/or other machine readable mediums for storing information. The term “machine readable medium” includes, but is not limited to portable or fixed storage devices, optical storage devices, wireless channels and various other mediums capable of storing, containing or carrying instruction(s) and/or data.

Furthermore, embodiments may be implemented by hardware, software, firmware, middleware, microcode, or any combination thereof. When implemented in software, firmware, middleware or microcode, the program code or code segments to perform the necessary tasks may be stored in a machine-readable medium such as a storage medium or other storage(s). A processor or circuit may perform the necessary tasks. A code segment may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, etc.

The various illustrative logical blocks, modules, circuits, elements, and/or components described in connection with the examples disclosed herein may be implemented or performed with a general purpose processor, a digital signal processor (DSP), an application specific integrated circuit (ASIC), a field programmable gate array (FPGA) or other programmable logic component, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing components, e.g., a combination of a (DSP) digital signal processor and a microprocessor, a number of microprocessors, one or more microprocessors in conjunction with a DSP core, or any other such configuration.

The methods or algorithms described in connection with the examples disclosed herein may be embodied directly in hardware, in a software module executable by a processor, or in a combination of both, in the form of processing unit, programming instructions, or other directions, and may be contained in a single device or distributed across multiple devices. A software module may reside in random access memory (RAM), flash memory, read-only memory (ROM), erasable programmable read-only memory (EPROM) memory, electrically erasable programmable read-only memory (EEPROM), registers, hard disk, a removable disk, a compact disc-read only memory (CD-ROM), or any other form of storage medium known in the art. A storage medium may be coupled to the processor such that the processor can read information from, and write information to, the storage medium. In the alternative, the storage medium may be integral to the processor.

Those of skill in the art would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system.

The various features of the invention described herein can be implemented in different systems without departing from the invention. It should be noted that the foregoing embodiments are merely examples and are not to be construed as limiting the invention. The description of the embodiments is intended to be illustrative, and not to limit the scope of the claims. As such, the present teachings can be readily applied to other types of apparatuses and many alternatives, modifications, and variations will be apparent to those skilled in the art.

What is claimed is:

1. A circuit, comprising:
a localized metal-insulator-metal capacitor array in a radio frequency front end circuit, which is integrated on a first die, and includes a localized common shared ground node within the localized metal-insulator-metal capacitor array;
a plurality of inductors; and
a plurality of radio frequency filters which each includes a plurality of passive resonant frequency circuits, and each of the plurality of passive resonant frequency circuits is implemented utilizing one or more metal-insulator-metal capacitors in the localized metal-insulator-metal capacitor array, and one or more of the plurality of inductors.

2. The circuit of claim 1, wherein the plurality of inductors is arranged at a periphery of the localized metal-insulator-metal capacitor array on the first die.

3. The circuit of claim 1, wherein the plurality of inductors is integrated on a second die, which is coupled to the first die.

4. The circuit of claim 1, wherein each of the metal-insulator-metal capacitors in the localized metal-insulator-metal capacitor array has a different capacitance value.

5. The circuit of claim 1, wherein the plurality of inductors are arranged on a first localized area of the first die, and the localized metal-insulator-metal capacitor array is arranged on a second localized area of the first die.

6. The circuit of claim 1, wherein the first die includes only passive circuits.

7. The circuit of claim 1, wherein the radio frequency front end circuit is incorporated into at least one of a user equipment, a communications device, a mobile phone, a smartphone, a tablet computer, and/or a laptop computer.

8. A method for manufacturing a circuit, comprising:
providing a localized metal-insulator-metal capacitor array in a radio frequency front end circuit, which is integrated on a first die, and includes a localized common shared ground node within the localized metal-insulator-metal capacitor array;
providing a plurality of inductors; and
providing a plurality of radio frequency filters in which each of the plurality of radio frequency filters includes a plurality of passive resonant frequency circuits, and each of the plurality of passive resonant frequency circuits is implemented utilizing one or more metal-insulator-metal capacitors in the localized metal-insulator-metal capacitor array, and one or more of the plurality of inductors.

9. The method of claim 8, wherein the plurality of inductors is arranged at a periphery of the localized metal-insulator-metal capacitor array on the first die.

10. The method of claim 8, wherein the plurality of inductors is integrated on a second die, which is coupled to the first die.

11. The method of claim 10, wherein the second die includes only passive circuits.

12. The method of claim 8, wherein each of the metal-insulator-metal capacitors in the localized metal-insulator-metal capacitor array has a different capacitance value.

13. The method of claim 8, wherein the plurality of inductors are arranged on a first localized area of the first die, and the localized metal-insulator-metal capacitor array is arranged on a second localized area of the first die.

14. The method of claim 8, wherein the first die includes only passive circuits.

15. A circuit, comprising:
a first integrated circuit die including a localized metal-insulator-metal capacitor array in a radio frequency front end circuit, and includes a localized common shared ground node within the localized metal-insulator-metal capacitor array;
a plurality of inductors;
means for coupling one or more metal-insulator-metal capacitors in the localized metal-insulator-metal capacitor array to one or more of the inductors to implement a plurality of passive resonant frequency circuits; and
means for coupling the plurality of passive resonant frequency circuits to implement a plurality of radio frequency filters.

16. The circuit of claim 15, wherein the plurality of inductors is arranged at a periphery of the localized metal-insulator-metal capacitor array on the first integrated circuit die.

17. The circuit of claim 15, wherein the plurality of inductors is integrated on a second integrated circuit die, which is coupled to the first integrated circuit die.

18. The circuit of claim 15, wherein each of the one or more metal-insulator-metal capacitors in the localized metal-insulator-metal capacitor array has a different capacitance value.

19. The circuit of claim 15, wherein the plurality of inductors are arranged on a first localized area of the first integrated circuit die, and the localized metal-insulator-metal capacitor array is arranged on a second localized area of the first integrated circuit die.

20. The circuit of claim 15, wherein the first integrated circuit die includes only passive circuits.
